(19) United States
(12) Patent Application Publication
(10) Pub. No.: US 2013/0111678 A1
(43) Pub. Date: May 9, 2013

(54) BRUSH BOX MODULE FOR CHEMICAL MECHANICAL POLISHING CLEANER

(71) Applicants: Hui Chen, Burlingame, CA (US); Allen L. D'Ambra, Burlingame, CA (US); Lakshmanan Karuppiah, San Jose, CA (US); Thomas H. Osterheld, Mountain View, CA (US)

(72) Inventors: Hui Chen, Burlingame, CA (US); Allen L. D'Ambra, Burlingame, CA (US); Lakshmanan Karuppiah, San Jose, CA (US); Thomas H. Osterheld, Mountain View, CA (US)

(73) Assignee: APPLIED MATERIALS, INC., Santa Clara, CA (US)

(21) Appl. No.: 13/291,945

(22) Filed: Nov. 8, 2011

(51) Int. Cl. H01L 21/02; A46B 13/00

(52) U.S. Cl. 15/77

(57) ABSTRACT

Embodiments of the invention generally relate to a method and apparatus for cleaning a substrate. Particularly, embodiments of the invention relate to an apparatus and method for cleaning a substrate using a scrub brush. One embodiment provides a brush box assembly for cleaning a substrate. The assembly comprises a chamber body having a cleaning chamber disposed therein, a rotatable chuck disposed in the cleaning chamber, and an edge cleaner module positioned adjacent the chuck.

### BACKGROUND OF THE INVENTION

1. Field of the Invention

Embodiments of the invention generally relate to an apparatus and a method for processing substrates. More particularly, embodiments of the invention provide apparatus and methods for cleaning semiconductor substrates.

2. Description of the Related Art

During fabrication of a semiconductor device, various layers, such as oxides, and metals, such as copper and tungsten, require planarization to remove steps or undulations prior to formation of subsequent layers. Planarization is typically performed mechanically, chemically, and/or electrically by pressing a device side of a semiconductor substrate against a polishing pad in the presence of a polishing solution, such as an abrasive compound, and moving the polishing pad relative to the semiconductor substrate. Multiple steps of polishing are generally performed using different polishing pads and polishing solutions to achieve desired flatness and smoothness on the device side of the substrate.

The planarization process can be followed by a cleaning process which removes residual polishing solution and/or particles from the substrate. Conventional cleaning processes generally include scrubbing the substrate surfaces with mechanical scrubbing devices having brushes made from porous or sponge like materials or bristles. When cleaning with brushes, the brushes generally approach the substrate from both the front side and the back side to contact the substrate and apply a force against the substrate. However, excess force applied to the substrate may damage the substrate. Additionally, motion control of the substrate in conventional cleaning apparatus is provided by drive rollers contacting an edge of the substrate. However, the control of the rotational velocity of the substrate is sometimes erratic due to excessive force applied to the substrate by the brushes. The excess force causes slippage between the drive rollers and the substrate, thus contributing to inefficient or poor cleaning results.

Therefore, there is a need for improved apparatus and methods for cleaning a substrate.

### SUMMARY OF THE INVENTION

Embodiments described herein generally relate to a method and apparatus for cleaning a substrate after a polishing process. Particularly, embodiments of the invention relate to an apparatus and method for cleaning a substrate using scrub brushes.

One embodiment provides a brush box assembly for cleaning a substrate. The assembly comprises a chamber body having a cleaning chamber disposed therein, a rotatable chuck disposed in the cleaning chamber, and an edge cleaner module positioned adjacent the chuck.

Another embodiment provides a brush box assembly for cleaning a substrate. The assembly comprises a chamber body having a cleaning chamber disposed therein, a rotatable chuck disposed in the cleaning chamber, a scrub brush disposed in the cleaning chamber adjacent the rotatable chuck, and a linearly movable substrate holder disposed in the cleaning chamber adjacent the rotatable chuck.

Another embodiment provides a brush box assembly for cleaning a substrate. The assembly comprises a base, at least a first chamber body disposed on the base, the chamber body having a cleaning chamber contained therein, a rotatable vacuum chuck disposed in the cleaning chamber, a substrate holder disposed in the cleaning chamber adjacent the rotatable chuck, the substrate holder being movable in a first direction relative to the rotatable chuck and a second direction relative to the rotatable chuck, the first direction being substantially orthogonal to the second direction, and an edge cleaner module positioned in the cleaning chamber adjacent the rotatable chuck.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic perspective view of a brush box assembly in accordance with one embodiment of the invention.

FIG. 1B is a schematic perspective view of a backside of the brush box assembly shown in FIG. 1A.

FIG. 2 is a side cross-sectional view of the brush box assembly of FIG. 1B.

FIG. 3A is a side cross-sectional view of the brush box module of FIG. 1A.

FIG. 3B is a cross-sectional view of the brush box module of FIG. 3A.

FIG. 4 is an isometric view of the drive assembly and the bracket that may be utilized in the brush box module of FIGS. 3A and 3B.

FIG. 5 is an isometric view of the edge cleaner module that may be utilized in the brush box module of FIGS. 3A and 3B.

FIG. 6 is an isometric view of the brush mounting frame that may be utilized on the brush box module of FIGS. 3A and 3B.

FIG. 7 is a schematic plan view of a polishing system where embodiments of the brush box assembly of FIG. 1A may be utilized.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

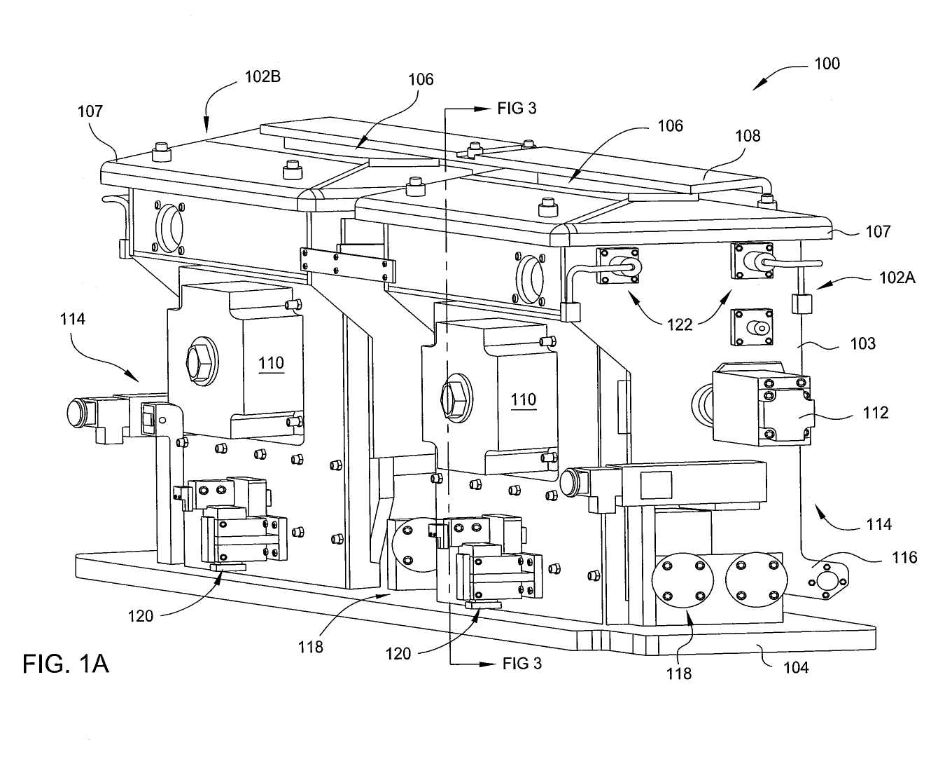

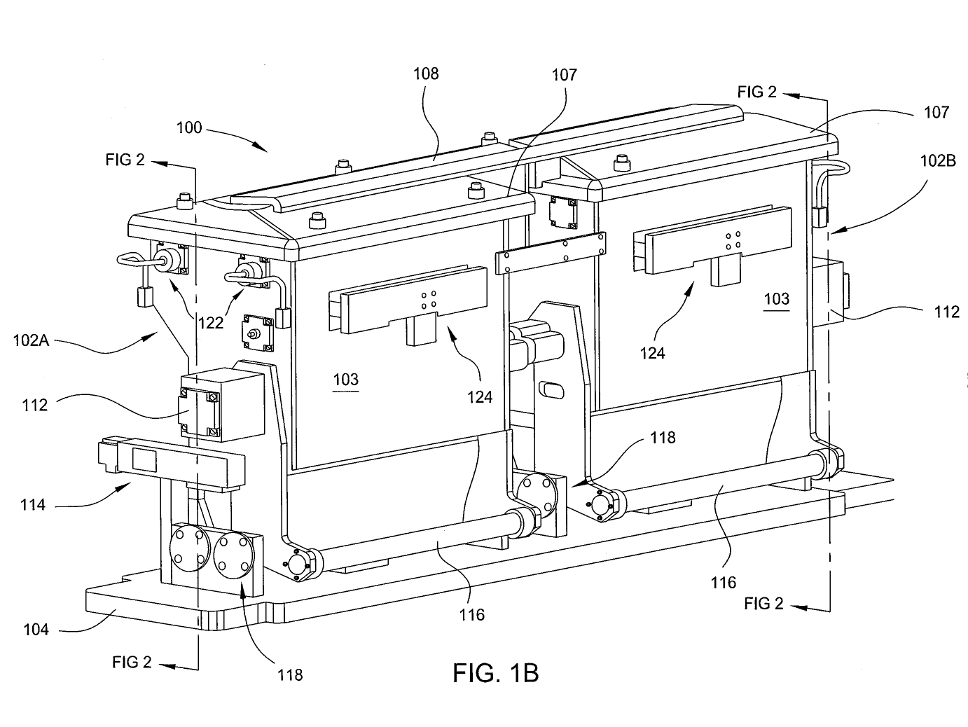

FIG. 1A is a schematic perspective view of a brush box assembly 100 in accordance with one embodiment of the invention. The brush box assembly 100 comprises two brush box modules 102A, 102B secured on a supporting base 104. Each of the brush box modules 102A, 102B include a chamber body 103 that encloses defines a cleaning chamber where a substrate is processed. Each brush box module 102A, 102B is configured to receive a substrate in a vertical orientation from a robot (not shown in FIG. 1A). The brush box assembly 100 or one or more of the brush box modules 102A, 102B may be used in a system configured to clean multiple substrates simultaneously.

Each of the brush box modules 102A, 102B include an opening 106 formed in a lid 107 of the brush box modules 102A, 102B. The opening 106 is configured to allow passage of a substrate into a cleaning chamber contained inside the chamber body 103 of the brush box modules 102A, 102B. During processing, the openings 106 may be closed by a cover 108 to prevent cleaning solution from splashing out of the cleaning chambers and to prevent outside particles from entering the cleaning chambers. A single cover 108 is configured to close the openings 106 of both brush box modules 102A, 102B. An actuator (not shown) is coupled to the cover 108 and is configured to facilitate opening and closing of the cover 108.

Each of the brush box modules 102A, 102B may be a substantially identical to each other and some common devices may be shown in this view while others are hidden. Common devices disposed on each of the brush box modules 102A, 102B include a drive system 110 that is coupled to a substrate support (not shown in FIG. 1A) for holding a substrate during processing, an actuator 112 for rotating a scrub brush during processing, and an actuator assembly 114 for controlling force of the scrub brush against the substrate. The actuator assembly 114 operates in conjunction with a mounting frame 116 that supports opposing ends of a scrub brush (not shown in FIG. 1A). The mounting frame 116 is movably coupled to the base 104 by a pivot bearing assembly 118, which allows the mounting frame 116 to pivot relative to the chamber body 103. Each of the brush box modules 102A, 102B also include a drive assembly 120 and fluid ports 122, both of which will be explained in greater detail below.

FIG. 1B is a schematic perspective view of a backside of the brush box assembly 100 shown in FIG. 1A. The common features are shown in FIG. 1B are the same as shown in FIG. 1A and will not be repeated for brevity. Each of the brush box modules 102A, 102B include an edge cleaner module 124 that facilitates cleaning the edge of a substrate during processing. The operation of the edge cleaner module 124 will be explained in greater detail below.

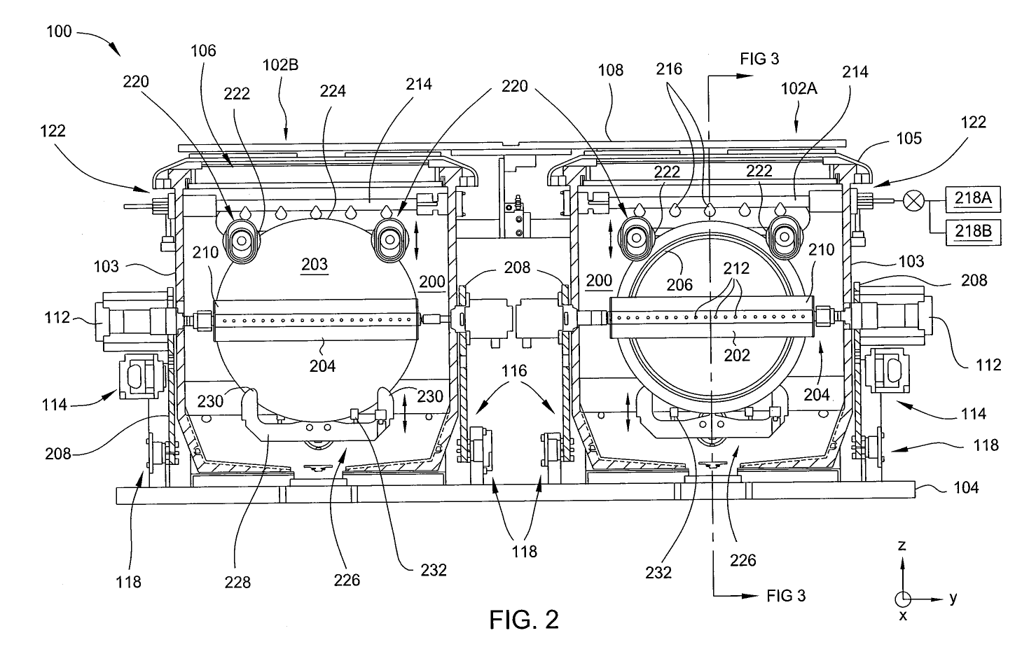

FIG. 2 is a side cross-sectional view of the brush box assembly 100 of FIG. 1B. Each of the brush box modules 102A, 102B contain a cleaning chamber 200. The cleaning chamber 200 includes an interior volume having a chuck 202 and a scrub brush 204 disposed therein. The cleaning chamber 200 also includes a roller assembly 220, one or more spray bars 214 (only one is shown in the cross-sectional view of FIG. 2), and a substrate holder 226. The chuck 202 is operably coupled to the drive system 110 (shown in FIG. 1A). The chuck 202 is configured to clamp the backside of a substrate 203 (shown in brush box module 102B) and facilitate rotational movement of the substrate 203 relative to the scrub brush 204. The device side of the substrate 203 interfaces with a surface of the scrub brush 204 to effect cleaning of the substrate 203. Rotation of the chuck 202 may be controlled by the drive system 110 such that the chuck 202 may be rotated at a rotational velocity of about 0 revolutions per minute (RPM) to about 1,000 RPM. In one embodiment, the chuck 202 is a vacuum chuck having a plurality of vacuum apertures 206 formed therein (shown in brush box module 102A). Vacuum is applied from the chuck 202 to clamp the backside of the substrate 203. The vacuum applied to the backside of the substrate 203 reliably clamps the substrate 203 to the chuck 202 and prevents slipping of the substrate 203 during processing. While only one substrate 203 is shown in brush box module 102B, a second substrate may be simultaneously processed in brush box module 102A to increase throughput.

Each scrub brush 204 is rotated by the actuator 112. Each scrub brush 204 is attached on each end to a pair of support arms 208 that are part of the mounting frame 116 disposed on each of the brush box modules 102A, 102B. The force applied to each scrub brush 204 is controlled by the respective actuator assembly 114. Each actuator assembly 114 is coupled between the chamber body 103 of the brush box modules 102A, 102B and at least one of the support arms 208 of a respective mounting frame 116. The actuator assembly 114 is adapted to move at least an end 210 of the scrub brush 204 laterally (X direction) toward or away from the substrate 203. Thus, pressure applied to the substrate 203 by the scrub brush 204 may be effectively controlled by the actuator assembly 114 to facilitate efficient cleaning of the substrate 203. As the substrate 203 is reliably held by the chuck 202, increased pressure against the substrate 203 may be applied without slippage of the substrate 203 as compared to conventional systems. The actuator 112 may be a rotational drive device powered by a rotational actuator. The support arms 208 are coupled to the pivot bearing assemblies 118 which provide relative movement of the support arms 208 relative to the base 104, thereby allowing pivoting movement of the scrub brush 204 relative to the substrate 203.

The scrub brush 204 may be a porous polymer material, such as polyvinyl acetate (PVA), or the scrub brush 204 may be a brush-type roller having bristles (not shown). A core of the scrub brush 204 includes a plurality of nozzles 212 for providing a cleaning solution or deionized water to the scrub brush 204 during processing.

The spray bar 214 is coupled to a fluid port 122 (shown in FIGS. 1A and 1B). The spray bar 214 includes a plurality of nozzles 216 oriented to direct a cleaning fluid to surfaces of the substrate 203 positioned in the cleaning chamber 200. The cleaning fluid provided by the spray bar 214 may include deionized water, acids, hydrogen peroxide (H₂O₂), ozone (O₃) isopropyl alcohol (ISA), and combinations thereof. Each nozzle 216 or combinations of nozzles 216 may be in communication with a discrete cleaning fluid supplies 218A, 218B to provide multiple cleaning fluids through a single spray bar 214. A single cleaning fluid may be provided through the spray bar 214 or combinations of cleaning fluids may be provided through the spray bar 214 simultaneously through different nozzles 216.

The substrate holder 226 is coupled to the drive assembly 120 (shown in FIG. 1A). The substrate holder 226 comprises a bracket 228 having at least one gripper 230 to receive a peripheral edge 224 of the substrate 203. The substrate holder 226 is utilized in transfer of the substrate 203 to and from the chuck 202. The bracket 228 is adapted to move at least vertically (Z direction) and laterally (X direction) relative to the chuck 202 to facilitate transfer of the substrate 203 to and from an end effector on a robot (both not shown) and the chuck 202.

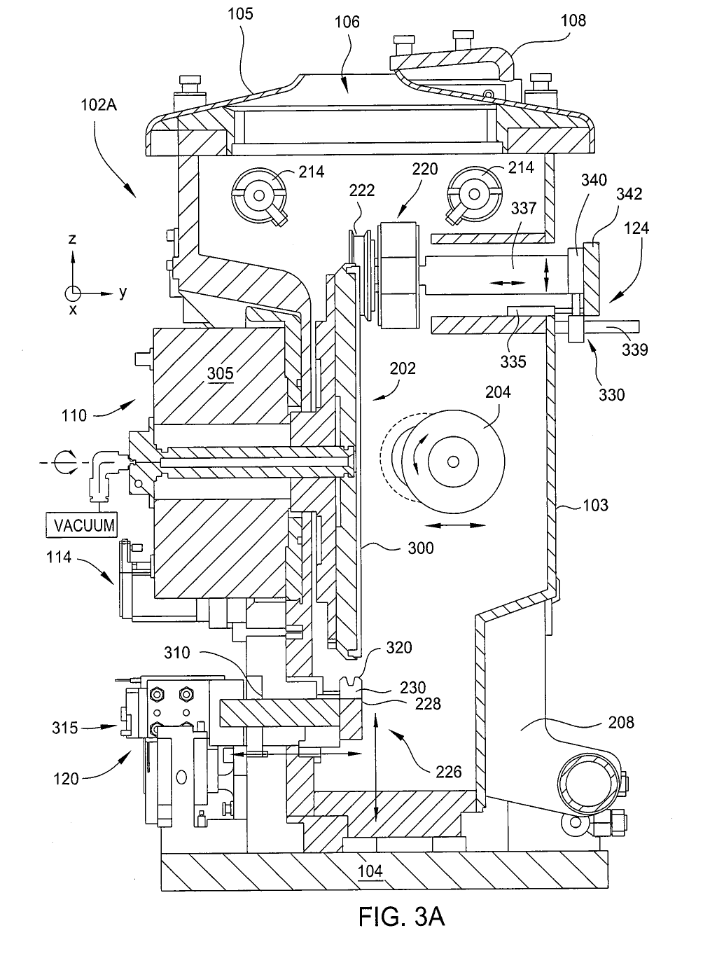

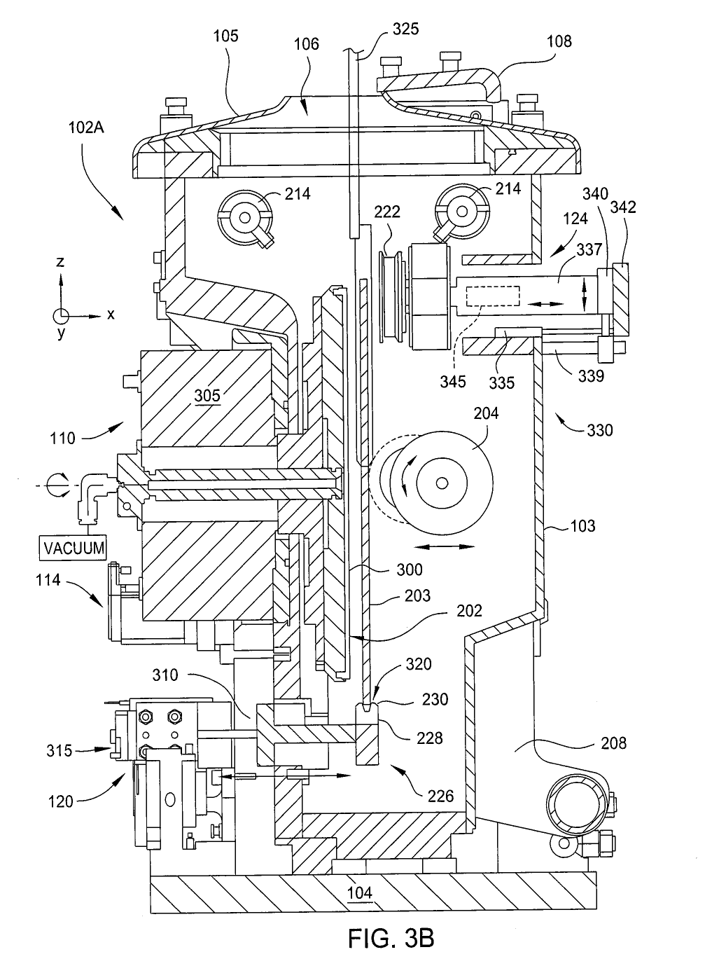

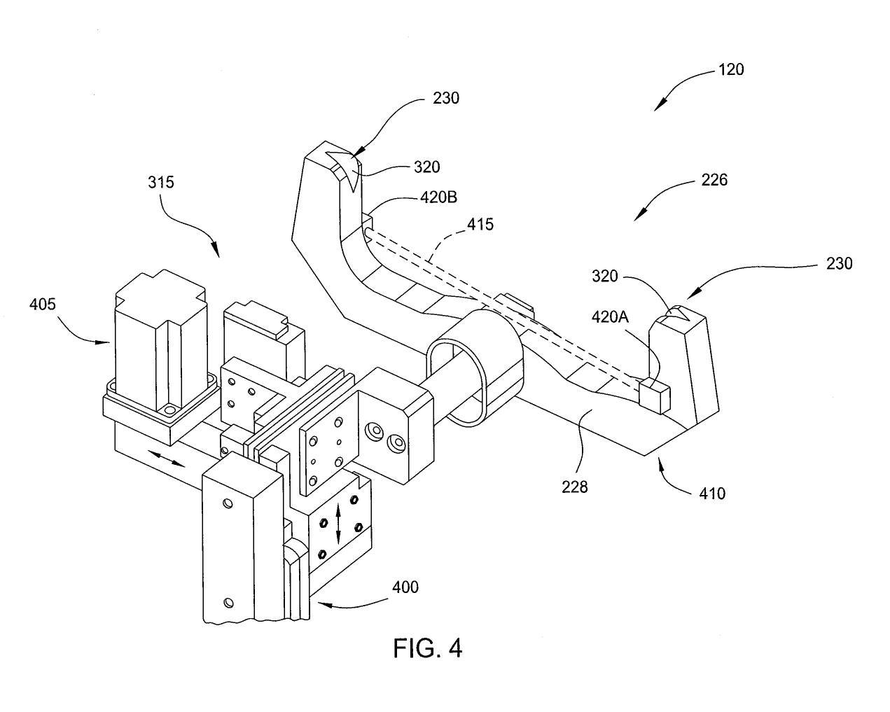

When an incoming substrate is transferred into the chamber body 103 by a robot, the grippers 230 are utilized to receive the substrate from the end effectors of the robot, and hold and support the substrate vertically (Z direction). When the end effectors have retracted clear the opening 106, the substrate holder 226 positions the substrate relative to the chuck 202. The positioning of the substrate may require vertical movement in the Z direction and lateral movement, such as in the X direction, to move the substrate toward the receiving surface of the chuck 202. When the substrate is aligned with the chuck 202, the chuck 202 is actuated to hold the substrate, which allows the substrate holder 226 to move away from the chuck 202 releasing the substrate from the grippers 230. The substrate holder 226 may move vertically (Z direction) downward and away from the peripheral edge 224 of the substrate to allow the substrate to rotate with the chuck 202 without interference from the grippers 230. When a processed substrate is to be transferred out of the chamber body 103, the movement of the substrate holder 226 is reversed to facilitate receipt of the substrate from the chuck 202 and transfer to the end effectors of a robot. The substrate holder 226 also includes a sensor device 232 to detect the presence or absence of a substrate. Operation of the substrate holder 226 and the drive assembly 120 is explained in further detail in the description of FIGS. 3A-4.

The roller assembly 220 is coupled to the edge cleaner module 124 (shown in FIG. 1B). Each roller assembly 220 includes one or more rollers 222 positioned to surround the peripheral edge 224 of the substrate 203. Each of the rollers 222 are controlled by the edge cleaner module 124 to may be adapted as idlers or to rotate relative to the substrate 203. Each of the rollers 222 are utilized to clean the peripheral edge 224 of the substrate 203 when the substrate 203 is positioned on the chuck 202. During transfer of the substrate 203, the roller assembly 220 is adapted to move away from the substrate 203 and the chuck 202 to allow the substrate 203 to pass vertically (Z direction) through the opening 106. Operation of the roller assembly 220 and the edge cleaner module 124 is explained in further detail in the description of FIG. 3B.

FIG. 3A is a side cross-sectional view of the brush box module 102A of FIG. 1A. The chuck 202 is shown in cross-section and includes a substrate receiving surface 300 that opposes a scrub brush 204. The chuck 202 is coupled to a motor 305 adapted to rotate the substrate receiving surface 300 about a first rotational axis while the scrub brush 204 is rotated in a second rotational axis that is orthogonal to the first rotational axis. The scrub brush 204 also moves laterally toward and away from the substrate receiving surface 300. Movement of the scrub brush 204 is controlled by the actuator 112 and the actuator assembly 114 (both shown in FIG. 2).

The drive assembly 120 is shown in partial cross-section. The drive assembly 120 comprises a support member 310 that is coupled between the bracket 228 and a drive assembly 315. The bracket 228 includes the gripper 230 which includes a slot 320 formed therein. The slot 320 is sized to receive a peripheral edge of a substrate (not shown) during transfer processes. The drive assembly 315 comprises one or more actuators operable to raise and lower the bracket 228, as well as move the bracket 228 laterally relative to the substrate receiving surface 300 of the chuck 202. The bracket 228 is shown in a position that does not interfere with the rotation of the substrate or the chuck 202 in FIG. 3A.

A portion of the edge cleaner module 124 is shown in FIG. 3A. The edge cleaner module 124 comprises a controller 330 configured to move the rollers 222 (only one roller 222 is shown FIG. 3A) linearly relative to the chamber body 103. In one embodiment, the controller 330 comprises a first actuator 335 and a second actuator 340. The first actuator 335 is operable to move the rollers 222 vertically while the second actuator 340 is operable to move the rollers 222 horizontally. Each of the rollers 222 are coupled to a shaft housing 337 (only one is shown in FIG. 3A). Each shaft housing 337 is coupled to a bracket 342. The bracket 342 allows each of the shaft housings 337 and rollers 222 to be moved in unison. One end of each of the first actuator 335 and the second actuator 340 are coupled between the bracket 342 and the chamber body 103. In one embodiment, the second actuator 340 is coupled to a guide member 339 that is coupled to the chamber body 103, which provides support for the second actuator 340 as the second actuator 340 moves with the bracket 342. Both of the first actuator 335 and the second actuator 340 may comprise a cylinder or a linear motor. The cylinder or linear motor may be powered electrically, hydraulically or pneumatically. Both of the first actuator 335 and the second actuator 340 may also include a slide device, a screw drive, gears, or other suitable device to impart linear movement to the bracket 228.

FIG. 3B is a cross-sectional view of the brush box module 102A of FIG. 3A during a transfer process. A substrate 203 is transferred into the brush box module 102A through the opening 106 by an end effector 325. During transfer, the bracket 228 may is moved laterally (X direction) to engage the edge of the substrate 203 and facilitate removal of the substrate 203 from the end effector 325. The end effector 325 may release the substrate 203 and be retracted after the substrate 203 is supported by the gripper 230. The bracket 228 may move laterally (X direction) and/or vertically (Z direction) toward the substrate receiving surface 300 to facilitate alignment of the substrate 203 relative to the substrate receiving surface 300. The chuck 202 may be actuated to hold the substrate 203 and the bracket 228 is moved to release the substrate 203 which is now supported by the chuck 202. The bracket 228 may be further actuated away from proximity of the substrate 203 and the chuck 202 to a position similar to the position shown in FIG. 3A.

Additionally, the edge cleaner module 124 moves the rollers 222 laterally (X direction) as shown in FIG. 3B. Movement of the rollers 222 facilitates clearance for the end effector 325 and the substrate 203 during transfer. In one embodiment, the edge cleaner module 124 comprises the controller 330 and the bracket 342 that moves the rollers 222 vertically (Z direction) and horizontally (X direction). When the substrate 203 is held on the substrate receiving surface 300 of the chuck 202, the edge cleaner module 124 moves the rollers 222 to a position similar to the position shown in FIG. 3A.

Each of the rollers 222 may be fabricated from a polymer, such as a polyurethane material commonly utilized in CMP systems. During processing, a substrate is held on the chuck 202 and is rotated. The rollers 222 are urged against the peripheral edge of the substrate as the substrate is rotated. The first actuator 335 may provide a down-force, such as about 2 pounds per square inch (psi) to about 4 psi, or greater. In one embodiment, rotation of at least some of the rollers 222 is not controlled externally (i.e., one or more of the rollers may be configured as idlers). This causes the rotation of the rollers 222 to be dependent on the rotation of the substrate. In one aspect, the down-force provided by the first actuator 335 is utilized to create slip between the surface of the roller 222 and the edge of the substrate. In one example, the chuck 202 may be rotated at about 120 revolutions per minute (rpm) and a down-force of about 3 psi is provided to the rollers 222, which creates about a 20 percent slippage that is utilized to clean the edge of the substrate. In another embodiment, the rotation of the rollers 222 is controlled by an optional torque controller 345 that may be utilized to apply a braking force or additional rotational force to the rollers 222. The torque controller 345 may comprise a motor disposed in or on the shaft housing 337.

As shown in FIGS. 3A and 3B, two spray bars 214 are shown. Each spray bar 214 may be used alone or in conjunction with each other before, during or after a cleaning process. For example, one or both of the spray bars 214 may be used during cleaning to apply a cleaning solution. When the cleaning process is completed, one or both of the spray bars 214 may be utilized to apply a fluid to the substrate 203 during transfer on the end effector 325. Excess fluid may be removed through a drain disposed on the brush box module 102A.

FIG. 4 is an isometric view of the drive assembly 315 and the bracket 228 that may be utilized in the brush box module 102A of FIGS. 3A and 3B. The drive assembly 315 comprises a vertical actuator assembly 400 and a horizontal actuator assembly 405. Both of the vertical actuator assembly 400 and the horizontal actuator assembly 405 may comprise a cylinder or a linear motor coupled to a drive assembly. The cylinder or motor may be powered electrically, hydraulically or pneumatically. The drive assembly 315 may include a slide device, a screw drive, gears, or other suitable device to impart linear movement to the bracket 228. The bracket 228 also includes a sensor system 410 adapted to detect the presence of a substrate. The sensor system 410 may comprise a proximity sensor or a thru-beam sensing system configured to transmit and receive a light beam 415. The sensor system 410 may comprise a sensor device having a transmitter 420A and a receiver 420B configured to utilize infrared or laser light. When a substrate is supported in the grippers 230, the light beam 415 is broken, which indicates the presence of the substrate.

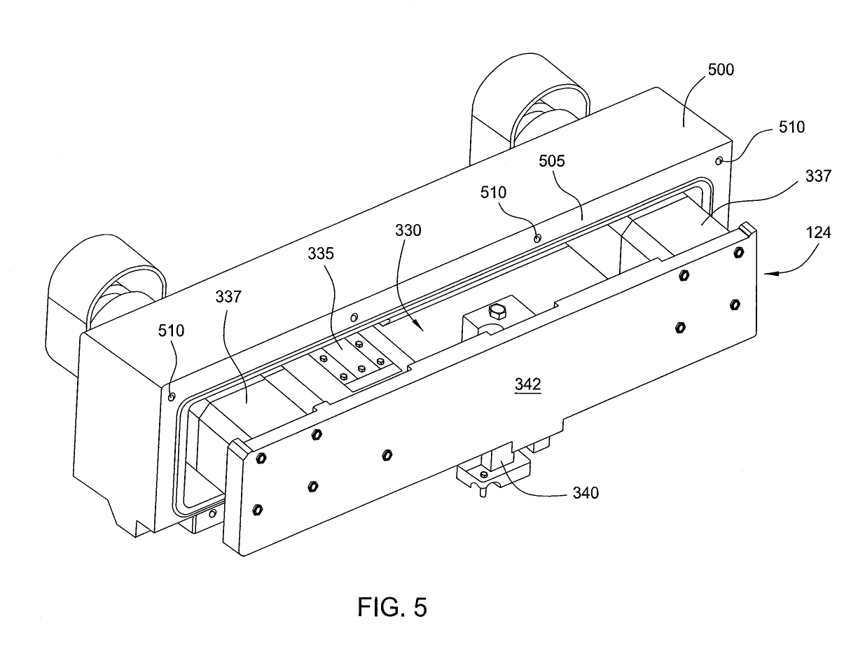

FIG. 5 is an isometric view of the edge cleaner module 124 that may be utilized in the brush box module 102A of FIGS. 3A and 3B. The edge cleaner module 124 includes a body 500 that at least partially encloses the shaft housings 337 and the first actuator 335. The body 500 includes a surface 505 configured to mount to an interior surface of the chamber body 103 (shown in FIGS. 3A and 3B). The body 500 also includes openings 510 for fasteners, such as bolts or screws.

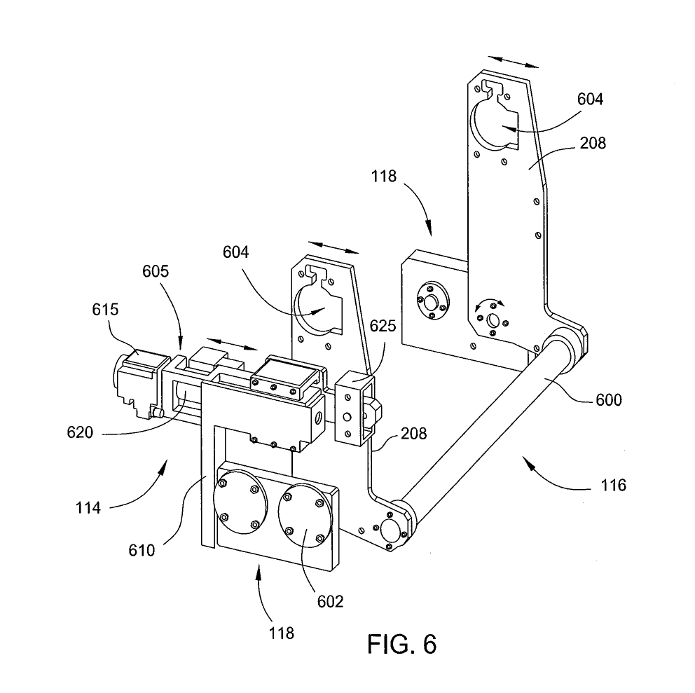

FIG. 6 is an isometric view of the mounting frame 116 that may be utilized on the brush box module 102A of FIGS. 3A and 3B. The mounting frame 116 comprises two support arms 208 that are coupled together by a support member 600. Each support arm 208 includes a mounting hole 604 where a scrub brush (shown in FIG. 2) is mounted. Each of the support arms 208 are coupled to a pivot bearing 602 of the pivot bearing assemblies 118. The support member 600 stabilizes the support arms 208 and allows the support arms 208 to move in unison. The actuator assembly 114 comprises an actuator assembly 605 that is fixed to the base (not shown) by a support member 610. The actuator assembly 605 includes a linear drive device 615 that may be a motor or a cylinder that is operated electrically, hydraulically or pneumatically. The linear drive device 615 may be coupled to a transmission member 620 to transmit motive force to an adjustable mounting block 625 disposed on one of the support arms 208. The transmission member 620 may be a shaft, a slide device, a screw mechanism or other linear drive mechanism. Actuation of the linear drive device 615 causes the transmission member 620 to apply a pulling or pushing force to the adjustable mounting block 625, which causes the support arms 208 to pivot about the pivot bearings 602 and move laterally.

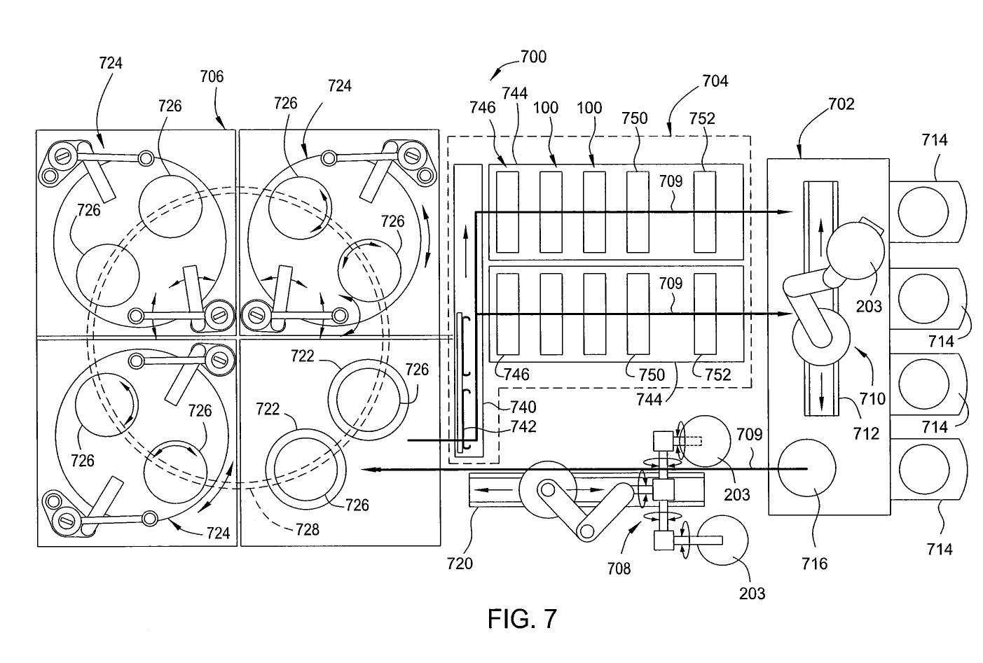

FIG. 7 is a schematic plan view of an exemplary polishing system 700 where embodiments of the brush box assembly 100 of FIG. 1A may be utilized. It is contemplated that the brush box assembly 100 may be used in polishing systems having other configurations.

The polishing system 700 generally includes a factory interface 702, a cleaner module 704 and a polishing module 706. A wet robot 708 is provided to transfer substrates 203 between the factory interface 702 and the polishing module 706. The wet robot 708 may also be configured to transfer substrates between the polishing module 706 and the cleaner module 704. In one mode of operation, the flow of substrates, such as semiconductor wafers or other work piece, through the polishing system 700 is indicated by arrows 709.

The factory interface 702 generally includes a dry robot 710 which is configured to transfer substrates 203 among one or more cassettes 714 for substrate storage. The factory interface 702 also includes one or more transfer platforms 716. In one embodiment, the dry robot 710 is mounted on a track 712 to allow the dry robot 710 to move between the cassettes 714 and the cleaner module 704.

The wet robot 708 generally is configured to retrieve the substrates 203 from the factory interface 702 in a face-up horizontal orientation, to flip the substrates 203 to a face-down horizontal orientation to the polishing module 706, and to rotate the substrates 203 to a vertical orientation to the cleaner module 704. The wet robot 708 is mounted on a track 720 and facilitates linear translation of the wet robot 708.

The polishing module 706 generally comprises a plurality of polishing heads 726 configured to retain substrates 203, load cups 722 configured to receive the substrates 203 from the wet robot 708 and transfer the substrates 203 to the polishing heads 726, and two or more polishing stations 724 configured to polish the substrates 203 supported on the polishing heads 726.

In one embodiment, the polishing heads 726 are coupled to an overhead track 728. The overhead track 728 is configured to transfer the polishing heads 726 and to position the polishing heads 726 selectively over the polishing stations 724 and load cups 722. The overhead track 728 has a generally circular configuration which allows the polishing heads 726 to be selectively rotated over and/or clear of the load cups 722 and the polishing stations 724.

During processing, the substrates 203 are transferred from the cassette 714 to the transfer platform 716 by the dry robot 710. The substrates 203 are then picked up by the wet robot 708 and transferred to the load cups 722. Processed substrates 203 are returned to the load cups 722 of the polishing module 706 for transfer by the wet robot 708 to the cleaner module 704. The cleaner module 704 generally includes a shuttle 740 and one or more cleaning stations 744 within the cleaner module 704. The shuttle 740 includes a transfer mechanism 742 which facilitates hand-off of the processed substrates from the wet robot 708 to the one or more cleaning stations 744.

The processed substrates are transferred from the shuttle 740 through the one or more cleaning stations 744 by an overhead transfer mechanism (not shown). In the embodiment depicted in FIG. 7, each of the cleaning stations 744 include a megasonic cleaner 746, two brush box assemblies 100 as described herein, a jet cleaner module 750 and a dryer 752. Dried substrates leaving the dryer 752 are rotated to a horizontal orientation for retrieval by the dry robot 710 which returns the dried substrates 203 to an empty slot in one of the cassettes 714.

Embodiments of a cleaner module 704 that may be adapted to benefit from the brush box assembly 100 and/or one or more of the brush box modules 102A, 102B described herein is a DESICA® cleaner, or a REFLEXION® GT polishing system, both available from Applied Materials, Inc., located in Santa Clara, Calif. It is contemplated that the brush box assembly 100 and/or one or more of the brush box modules 102A, 102B may be utilized in other cleaner modules, including those from other manufacturers.

In one embodiment, a transfer device (not shown) is used to retrieve and advance substrates 203 through the cleaner module 704 sequentially, from the megasonic cleaner 746 to the brush box assemblies 100 then to the jet cleaner module 750 and the dryer 752. The megasonic cleaner 746 is configured to perform an efficient cleaning step using megasonic energy. The jet cleaner module 750 is configured to perform a cleaning step using pressurized liquid. The dryer 752 is configured to quickly dry a substrate after cleaning to remove bath residue and prevent streaking and spotting caused by evaporation. The brush box module 748 is configured to perform a cleaning step using mechanical contact, such as scrubbing motion. Embodiments of a brush box module are described in FIGS. 1A-2 of the present application.

Embodiments of the brush box assembly 100 as described herein increases the efficiency of a cleaning operation and provides reduced downtime for maintenance. Utilization of the chuck 202 provides a stable substrate support, which supports the backside of the substrate as well as prevents slipping of the substrate during cleaning. Additionally, greater scrub brush pressure may be applied to substrate during cleaning, which promotes more efficient cleaning and minimizes cleaning time. The utilization of a single scrub brush 204 and/or a single actuator assembly 114 per scrub brush 204 provides enhanced force management during cleaning. Additionally, as some conventional cleaners utilize multiple brushes each having multiple force actuators, maintenance and replacement of parts is lessened. Further, the integrated edge cleaner module 124 may be configured to take advantage of slip between rollers 222 and a substrate to facilitate edge cleaning, which increases efficiency of the brush box assembly 100.

While the foregoing is directed to embodiments of the present invention, other and further embodiments of the invention may be devised without departing from the basic scope thereof, and the scope thereof is determined by the claims that follow.

What is claimed is:

1. A brush box assembly for cleaning a substrate, the assembly comprising:
a chamber body having a cleaning chamber disposed therein;
a rotatable chuck disposed in the cleaning chamber; and
an edge cleaner module positioned in the cleaning chamber adjacent the chuck.

2. The assembly of claim 1, wherein the rotatable chuck is a vacuum chuck.

3. The assembly of claim 1, wherein the edge cleaner module is positioned adjacent an upper portion of the rotatable chuck, the assembly further comprising a substrate holder positioned in the cleaning chamber adjacent a lower portion of the rotatable chuck.

4. The assembly of claim 3, wherein the substrate holder is coupled to an actuator operable to move the substrate holder relative to the rotatable chuck.

5. The assembly of claim 3, wherein the substrate holder comprises a sensor device.

6. The assembly of claim 1, wherein the edge cleaner module comprises a roller assembly having two rollers.

7. The assembly of claim 6, wherein the two rollers are coupled to a controller operable to move the rollers relative to the chuck.

8. The assembly of claim 7, wherein the controller comprises a linear actuator.

9. The assembly of claim 7, wherein the controller comprises a first linear actuator to move the rollers in a first direction and a second linear actuator to move the rollers in a second direction that is orthogonal to the first direction.

10. The assembly of claim 1, further comprising:
a single scrub brush positioned adjacent the rotatable chuck.

11. A brush box assembly for cleaning a substrate, the assembly comprising:
a chamber body having a cleaning chamber disposed therein;
a rotatable chuck disposed in the cleaning chamber;
a scrub brush disposed in the cleaning chamber adjacent the rotatable chuck; and
a linearly movable substrate holder disposed in the cleaning chamber adjacent the rotatable chuck.

12. The assembly of claim 11, wherein the rotatable chuck is a vacuum chuck.

13. The assembly of claim 11, wherein the substrate holder is coupled to an actuator to move the substrate holder relative to the chuck.

14. The assembly of claim 11, wherein the substrate holder comprises a sensor system operable to detect the presence of a substrate in the substrate holder.

15. The assembly of claim 11, wherein the substrate holder is positioned adjacent a lower portion of the rotatable chuck, and the assembly further comprises an edge cleaner module positioned in the cleaning chamber adjacent an upper portion of the rotatable chuck.

16. A brush box assembly for cleaning a substrate, the assembly comprising:
a base;
at least a first chamber body disposed on the base, the chamber body having a cleaning chamber contained therein;
a rotatable vacuum chuck disposed in the cleaning chamber;
a substrate holder disposed in the cleaning chamber adjacent the rotatable chuck, the substrate holder being movable in a first direction relative to the rotatable chuck and a second direction relative to the rotatable chuck, the first direction being substantially orthogonal to the second direction; and
an edge cleaner module positioned in the cleaning chamber adjacent the rotatable chuck.

17. The assembly of claim 16, wherein the substrate holder is coupled to an actuator to move the substrate holder relative to the chuck.

18. The assembly of claim 16, wherein the substrate holder comprises a sensor system.

19. The assembly of claim 16, wherein the edge cleaner module is positioned adjacent to an upper portion of the rotatable chuck and the substrate holder is positioned adjacent to a lower portion of the rotatable chuck.

20. The assembly of claim 16, further comprising:
a second chamber body disposed on the base, the second chamber body being substantially identical to the first chamber body.
